(19) United States
(12) Patent Application Publication
(10) Pub. No.: US 2007/0240646 A1
(43) Pub. Date: Oct. 18, 2007

(54) Substrate treatment apparatus

(75) Inventor: Jong-Jin Jun, Sungnam City (KR)

Correspondence Address: KED & ASSOCIATES, LLP, P.O. Box 221200, Chantilly, VA, 20153-1200, US

(73) Assignee: Advanced Display Process Engineering Co., Ltd.

(21) Appl. No.: 11/783,689

(22) Filed: Apr. 11, 2007

(30) Foreign Application Priority Data
Apr. 13, 2006 (KR) 10-2006-0033518

(51) Int. Cl. C23F 1/00; C23C 16/00

(52) U.S. Cl. 118/729; 156/345.54

(57) ABSTRACT

The present invention relates to a substrate treatment apparatus, and more particularly, to a substrate treatment apparatus, wherein lift pins can be installed while the levels of the lift pins are easily adjusted using a tool such as a wrench. A substrate treatment apparatus of the present invention comprises a chamber; a pin plate provided inside or outside the chamber; a driving means for lifting or lowering the pin plate; and at least one lift pin that penetrates through the pin plate so that the lift pin is coupled to the pin plate, and has a tool insertion recess formed at a lower end of the lift pin.

### BACKGROUND OF THE INVENTION

1. Field of Invention

The present invention relates to a substrate treatment apparatus, and more particularly, to a substrate treatment apparatus, wherein lift pins can be installed while the levels of the lift pins are easily adjusted using a tool such as a wrench.

2. Description of the Related Art

Generally, fabrication of a semiconductor device and an LCD panel requires plasma treatment of a substrate. In such plasma treatment of a substrate, a substrate is loaded into and fixed in a vacuum chamber and process gases and high frequency power are applied thereto to generate plasma, thereby performing predetermined plasma treatment.

A conventional substrate treatment apparatus will be described with reference to FIG. 1. A vacuum chamber 10 includes an upper electrode 12 into which process gases are applied, and an electrode portion 20 to which high frequency power is applied.

A substrate S is loaded into the chamber 10 from the outside by a carrying robot, and the loaded substrate S is put down on and fixed to the electrode portion 20.

At this time, a substrate-lifting unit is provided to safely and correctly perform the process of receiving the substrate S from the carrying robot and putting down it on the electrode portion 20. The substrate-lifting unit includes a plurality of lift pins 31 for supporting the substrate S, a pin plate 32 having an upper surface formed with coupling recesses 32a in which the lift pins 31 are to be secured, and a driving means 30 for lifting or lowering the pin plate 32.

The substrate-lifting unit further includes a cylinder shaft 33 for transmitting a driving force from the driving means 30 to the pin plate 32, and bellows 40 for hermetically wrapping the lift pins 31 between the vacuum chamber 10 and the pin plate 32.

Meanwhile, when the substrate S is seated on the electrode portion 20 by lowering the lift pins 31, there is a phenomenon in which the substrate S is slid on the electrode portion 20. To prevent this phenomenon, the plurality of lift pins 31 are arranged such that the levels thereof gradually increase from a central lift pin to outermost lift pins. That is, the substrate S is lowered in a state where a central portion thereof is sagged.

To this end, the lift pins 31 are configured such that the levels thereof can be adjusted. The lift pins 31 are arranged at adjusted levels.

More specifically, as shown in an enlarged portion of FIG. 1, one or more washers 34 with a predetermined thickness are inserted into each of the coupling recesses 32a formed in the pin plate 32, and the lift pin 31 is then coupled on the washers. The level of the lift pin 31 can be adjusted according to the thickness or number of the washers 34 that are inserted in advance.

However, in such a case, the lift pin 31 itself is unstably coupled due to the washers 34 placed below the lift pin 31. Therefore, there is a problem in that the lift pin 31 is arbitrarily moved due to external impact or vacuum pressure so that the level of the lift pin 31 cannot be constantly maintained.

Further, since the washers 34 have a standardized thickness, an additional washer should be manufactured and inserted in order to ensure a correct level. Thus, there is a problem in that work is complicated and becomes cumbersome. Even though the level of the lift pin can be adjusted using such an additional washer separately manufactured, there is a problem in that it is difficult to minutely adjust the level.

### SUMMARY OF THE INVENTION

The present invention is conceived to solve the aforementioned problems in the prior art. An object of the present invention is to provide a substrate treatment apparatus, wherein lift pins can be installed while the levels of the lift pins are easily adjusted using a tool such as a wrench.

According to the present invention for achieving the object, there is provided a substrate treatment apparatus comprising a chamber; a pin plate provided inside or outside the chamber; a driving means for lifting or lowering the pin plate; and at least one lift pin that penetrates through the pin plate so that the lift pin is coupled to the pin plate, and has a tool insertion recess formed at a lower end of the lift pin.

With this configuration, the lower end of the lift pin, which protrudes beyond a bottom surface of the pin plate while penetrating therethrough, is operated using a tool such as a wrench so that the level of the lift pin can be adjusted to a desired level.

Further, a first nut may be fastened to the lower end of the lift pin below the pin plate in order to fix the lift pin of which the level has been adjusted to the desired level.

Moreover, a second nut may be further consecutively fastened below the first nut in order to prevent the first nut from being arbitrarily moved.

In addition, the apparatus may further comprise a protection cap for keeping the coupled portion of the lift pin in a hermetic state below the pin plate.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a sectional view showing a conventional substrate treatment apparatus;

FIG. 2 is a sectional view showing a substrate treatment apparatus according to an embodiment of the present invention;

FIG. 3 is an enlarged sectional view of a main portion of the substrate treatment apparatus shown in FIG. 2; and

FIG. 4 is a sectional view showing a substrate treatment apparatus according to another embodiment of the present invention.

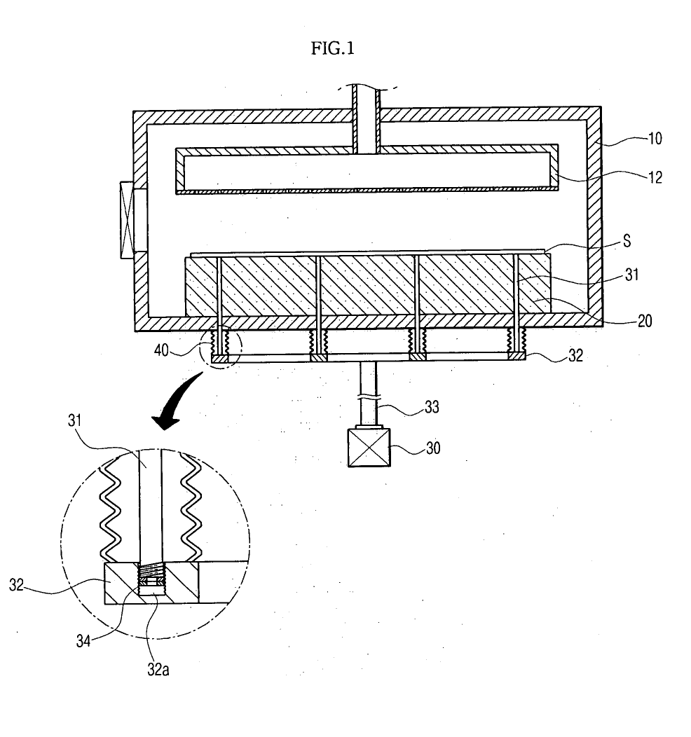

### EXPLANATION OF REFERENCE NUMERALS FOR MAIN PORTIONS IN DRAWINGS

| | |
|---|---|
| 100: Vacuum chamber | 110: Electrode portion |
| 120: Lift pin | 121: Tool insertion recess |
| 122: Pin plate | 128: Nut |
| 128a: Auxiliary nut | 134: Cylinder shaft |
| 136: Driving means | 140: Protection cap |

### DETAILED DESCRIPTION OF THE PREFERRED EMBODIMENTS

Hereinafter, the constitutions and operations of embodiments of the present invention will be described in detail with reference to the accompanying drawings.

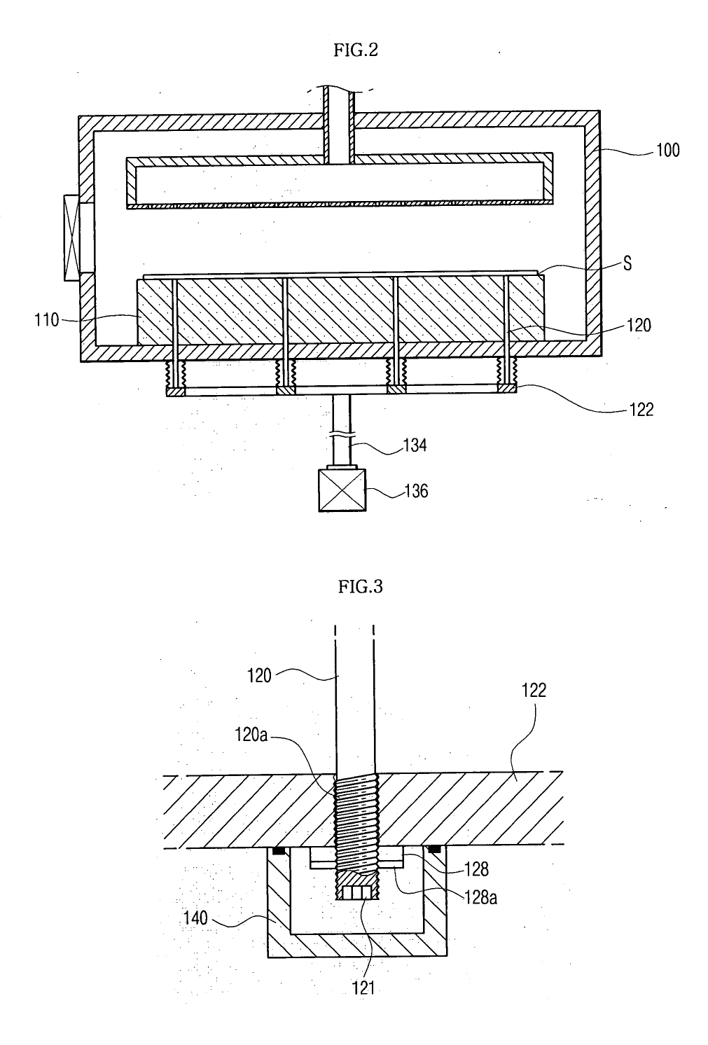

Referring to FIG. 2, a subject treatment apparatus according to an embodiment of the present invention includes a chamber 100, an upper electrode, an electrode portion 110, and a substrate-lifting unit. The substrate-lifting unit includes a plurality of lift pins 120 for supporting a substrate S to lift or lower the substrate, a pin plate 122 on which the lift pins 120 are installed, a driving means 136 for generating a driving force, and a cylinder shaft 134 for transmitting the driving force. Further, it can be seen that the pin plate 122 is provided outside and below the chamber 100.

Referring to FIG. 3, in particular, it can be seen that the lift pins 120 are installed to penetrate through the pin plate 122 in this embodiment. Moreover, an outer periphery of each of the lift pins 120 and an inner periphery of each of holes in the pin plate 122 are formed with threads 120a.

In addition, a tool insertion recess 121 into which a tool (not shown) such as a wrench is to be inserted and engaged is formed at a lower end of the lift pin 120. Therefore, the level of the lift pin can be easily adjusted by inserting the tool such as a wrench into the tool insertion recess 121 and rotating the lift pin 120.

Further, the lift pin 120 of which the level has been adjusted should be prevented from being arbitrarily moved due to external impact, vacuum pressure or the like. Thus, it is required to fix the lift pin 120 of which the level has been adjusted. In this embodiment, a nut 128 is fastened to the lower end of the lift pin 120 protruding beyond a bottom surface of the pin plate 122. That is, the movement of the lift pin 120 is prevented by bringing the nut 128 into close contact with the pin plate 122. Furthermore, to prevent the nut 128 from being arbitrarily moved, an auxiliary nut 128a with the same structure as the nut 128 is also consecutively fastened.

Since the pin plate 122 is installed outside the vacuum chamber 100 in this embodiment, it is necessary to keep the coupled portion of the lift pin 120 in a hermetic state in order to maintain the degree of vacuum in the vacuum chamber 100. To this end, it can be understood that a protection cap 140 should be further provided below the pin plate 122.

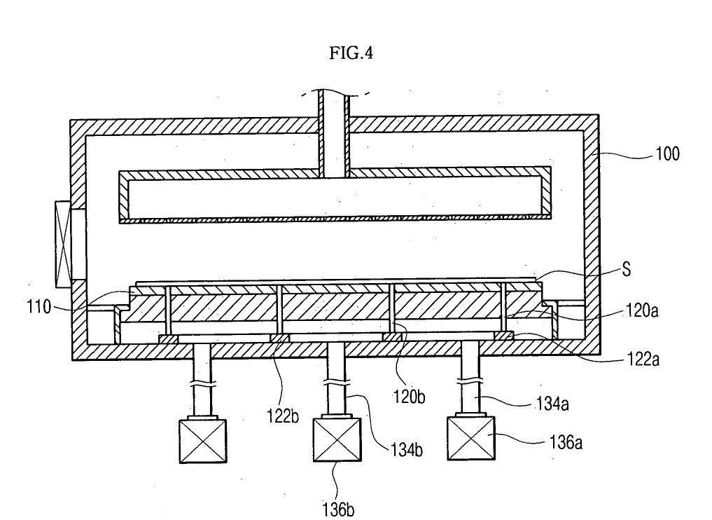

FIG. 4 shows a substrate treatment apparatus according to another embodiment of the present invention. It can be seen from the figure that pin plates 122a and 122b are installed inside a vacuum chamber 100.

Further, among a plurality of lift pins, a center pin 120b for lifting or lowering a central portion of a substrate S and an edge pin 122a for lifting or lowering an edge of the substrate are independently lifted or lowered. To this end, a center pin plate 122b to which the center pin 120b is coupled and an edge pin plate 122a to which the edge pin 120a is coupled are separately formed.

Moreover, a cylinder shaft 134b and a driving means 136b for driving the center pin plate 122b, and a cylinder shaft 134a and a driving means 136a for driving the edge pin plate 122a are also separately formed.

With this configuration, the central portion and edge of the substrate S can be independently lifted or lowered.

For example, the center pin plate 122b and the edge pin plate 122a may be configured such that they are lifted or lowered with a time interval. That is, the edge pin plate 122a is first lifted or lowered and the center pin plate 122b is then lifted or lowered. At this time, it is preferred that the lifting or lowering speed of the center pin plate 122b be greater than the lifting or lowering speed of the edge pin plate 122a. This is to achieve the horizontal state of the substrate when the substrate S reaches a top position while the edge pin plate 122a earlier begins to be lifted or lowered than the center pin plate 122b.

Otherwise, it is also possible to first lift the edge pin plate 122a when the pin plates are lifted but to first lower the center pin plate 122b when the pin plates are lowered.

According to the present invention, the lift pins of the substrate treatment apparatus can be installed while the levels of the lift pins are easily adjusted using a tool such as a wrench.

What is claimed is:

1. A substrate treatment apparatus, comprising:
a chamber;
a pin plate provided inside or outside the chamber;
a driving means for lifting or lowering the pin plate; and
at least one lift pin penetrating through the pin plate so that the lift pin is coupled to the pin plate, the lift pin having a tool insertion recess formed at a lower end of the lift pin.

2. The apparatus as claimed in claim 1, wherein the lift pin is threadly coupled to the pin plate.

3. The apparatus as claimed in claim 1, wherein a first nut is fastened to the lower end of the lift pin below the pin plate in order to fix the lift pin that has been installed at a set level.

4. The apparatus as claimed in claim 3, wherein a second nut is further consecutively fastened below the first nut in order to prevent the first nut from being arbitrarily moved.

5. The apparatus as claimed in claim 1, further comprising a protection cap for keeping the coupled portion of the lift pin in a hermetic state below the pin plate.
